(19) United States
(12) Patent Application Publication
(10) Pub. No.: US 2024/0184209 A1
(43) Pub. Date: Jun. 6, 2024

(54) LITHOGRAPHIC PROCESSES FOR MAKING POLYMER-BASED ELEMENTS

(71) Applicant: Intel Corporation, Santa Clara, CA (US)

(72) Inventors: Changhua LIU, Chandler, AZ (US); Bai NIE, Chandler, AZ (US); Robert MAY, Chandler, AZ (US)

(21) Appl. No.: 18/060,593

(22) Filed: Dec. 1, 2022

(51) Int. Cl. G03F 7/20; G03F 7/00

(52) U.S. Cl. CPC G03F 7/201; G03F 7/0007; G03F 7/2006; G03F 7/2014

(57) ABSTRACT

The present disclosure is directed to a lithographic patterning system including a stage for supporting a substrate with a photo-definable polymer layer, a first actinic radiation source, which is configured to propagate light along a first optical axis, a first mask for patterning the propagated light from the first actinic radiation source, a second actinic radiation source, which is configured to propagate light along a second optical axis, and a second mask for patterning the propagated light from the second actinic radiation source. In a method, first and second propagated lights form an intersection in the photo-definable polymer layer, and a patterned semiconductor component is formed at the intersection.

### BACKGROUND

For integrated circuit design and fabrication, the need to improve performance and lower of costs are constant challenges. Cost savings may be potentially realized by building selected semiconductor elements or components using photolithographic processes rather than using conventional fabrication methods.

Conventional photolithography provides a vertical projection of actinic radiation that is used to expose a resist layer to produce structures in a semiconductor layer below the resist layer. However, the use of patternable photo-definable polymers has the potential to form structures that may be incorporated into semiconductor devices. For example, the use of integrated optical elements (e.g., waveguides and lenses) may be a key enabler for more efficient silicon photonics packaging, but its very high alignment requirements make the packaging process expensive and unfriendly for high-volume manufacturing (HVM). The use of improved lithography systems having, for example, tiltable stages may be capable of producing a single-mode polymer waveguide with good optical properties as an HVM process.

It may be possible to lithographically produce a polymer waveguide since lithographic systems will typically have very good x and y-direction alignments, but the challenge lies in their z-direction alignment, which is normally not controllable. It is presently very hard to achieve sub-micron level accuracy that is typically needed for good single-model light signal coupling efficiency in a polymer waveguide. Accordingly, a lithography system that has precise 3D positional control, i.e., control of the exposure energy distribution throughout the photosensitive material, is needed to produce a wide range of semiconductor elements, such as a waveguide, a taper, optical lenses, and curved mirrors, that may meet the alignment accuracy requirement for semiconductor devices, including silicon photonic packages.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the present disclosure. The dimensions of the various features or elements may be arbitrarily expanded or reduced for clarity. In the following description, various aspects of the present disclosure are described with reference to the following drawings, in which:

FIG. 1 shows an exemplary representation of a lithographic patterning system according to an aspect of the present disclosure;

FIG. 2A shows an exemplary representation of light paths from two actinic radiation sources and FIG. 2B shows a component formed at the intersection of the two light paths according to an aspect of the present disclosure;

FIG. 3 shows an exemplary representation of a waveguide formed by a present lithographic patterning system in a silicon photonics package according to an aspect of the present disclosure;

FIGS. 4A and 4B show an exemplary representation of multiple optic lenses formed by a present lithographic patterning system according to an aspect of the present disclosure;

FIGS. 5A and 5B show exemplary representations of optic lenses formed by a present lithographic patterning system attached to silicon photonics devices according to an aspect of the present disclosure; and

FIG. 6 shows a simplified flow diagram for an exemplary method according to an aspect of the present disclosure.

### DETAILED DESCRIPTION

The following detailed description refers to the accompanying drawings that show, by way of illustration, specific details, and aspects in which the present disclosure may be practiced. These aspects are described in sufficient detail to enable those skilled in the art to practice the present disclosure. Various aspects are provided for devices, and various aspects are provided for methods. It will be understood that the basic properties of the devices also hold for the methods and vice versa. Other aspects may be utilized and structural, and logical changes may be made without departing from the scope of the present disclosure. The various aspects are not necessarily mutually exclusive, as some aspects can be combined with one or more other aspects to form new aspects.

The present disclosure is directed to a lithographic patterning system including a stage for supporting a substrate with a photo-definable polymer layer, a first actinic radiation source, which is configured to propagate light along a first optical axis, a first mask for patterning the propagated light from the first actinic radiation source, a second actinic radiation source, which is configured to propagate light along a second optical axis, and a second mask for patterning the propagated light from the second actinic radiation source. The propagated light from the first actinic radiation source forms an intersection in the photo-definable polymer layer with the propagated light from the second actinic radiation source, and a patterned semiconductor component is formed at the intersection.

In another aspect, the present disclosure is directed to a semiconductor component made from a photoresist material that is shaped by a lithographic patterning process, which is performed by a lithographic patterning system with first and second actinic radiation sources that direct, respectively, a first propagated light and a second propagated light to form an intersection within the photoresist material. The first propagated light initiates a partial formation of the semiconductor component in the photoresist material and the second propagated light completes the formation of the semiconductor component in the photoresist material, whereby the semiconductor component is formed at the intersection within the photoresist material. In an aspect, the shaped photoresist material may be an optical waveguide or an optical lens for a silicon photonic package.

In yet another aspect, the present disclosure is directed to a method providing a lithographic patterning system having a first and second actinic radiation sources, a stage, a first mask for use with the first actinic radiation source, and a second mask for use with the second actinic radiation source. The first actinic radiation source is positioned to direct a first propagated light at the stage at a first angle relative to a central axis, which is orthogonal to the stage and the second actinic radiation source is positioned to direct a second propagated light at the stage at a second angle relative to the central axis. In addition, a photo-definable polymer may be positioned on top of the stage, and the first actinic radiation source is activated to partially form a component in the photo-definable polymer and the second actinic radiation source is activated to completely form the component in the photo-definable polymer.

In an aspect, the use of two angled light exposures enables the control of the x-, y- and z- positions of the exposed or cured cross-section in the x-z plane. For example, the power level of a first UV exposure may be set below a level needed to cure a present photo-definable polymer (i.e., photoresist material) and after a second UV exposure, it is only at the intersection of the UV exposures is the combined dose high enough to amplify or cure the polymer resist. In another aspect, a first UV exposure may be followed by second IR exposure, which generates localized heat for chemically amplifying the polymer resist. The intersection or cross-section between the first and second exposures will form the photo-definable polymer cross-section in 3D space.

Using the present system and method, a wide range of optical elements/components, such as waveguides, tapers, optical lenses, and curved mirrors, may be created with precise 3D positional control, and these components will be able to meet the alignment accuracy requirements of silicon photonic packages.

The technical advantages of the present disclosure include, but are not limited to:
(i) Providing a lithographic patterning system that uses two angled light exposures to enable the control of the x-, y- and z- positions in amplifying a photoresist material;
(ii) Providing a method to produce lithographic components that will be able to meet the alignment accuracy requirements of silicon photonic packages; and
(iii) Providing high-volume manufacturing using lithographic patterning for semiconductor components, and more specifically, optical elements.

To more readily understand and put into practical effect the present thermocompression bonding tool with chip gap height control, which may be used for panel-level manufacturing to improve yield and performance, particular aspects will now be described by way of examples provided in the drawings that are not intended as limitations. The advantages and features of the aspects herein disclosed will be apparent through reference to the following descriptions relating to the accompanying drawings. Furthermore, it is to be understood that the features of the various aspects described herein are not mutually exclusive and can exist in various combinations and permutations. For the sake of brevity, duplicate descriptions of features and properties may be omitted.

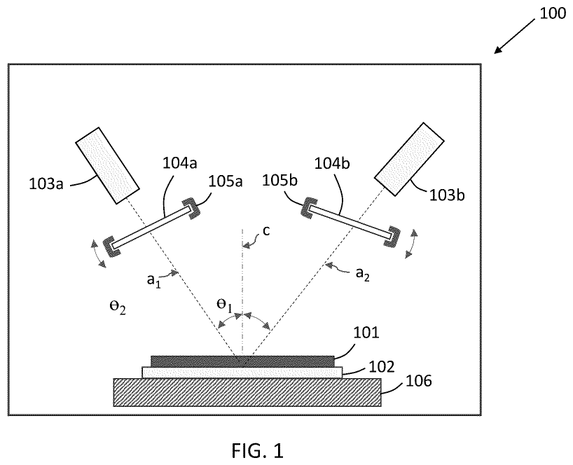

In FIG. 1, an exemplary representation of a present lithographic patterning system 100 is shown according to an aspect of the present disclosure. The lithographic patterning system 100 may have a photo-definable polymer or photoresist layer 101 supported by a substrate 102 positioned on a stage 106 and a first actinic radiation source 103a and a second actinic radiation source 103b.

In an aspect, the first actinic radiation source 103a and the second actinic radiation source 103b may be identical ultraviolet (UV) lamps or UV lasers. In this aspect, the two UV exposures may be at a lower than curing dose and only the exposure energy at the intersection is high enough to cure the photoresist polymer. In another aspect, the first actinic radiation source 103a may be a UV lamp or UV laser, and the second actinic radiation source 103b may be an infrared (IR) lamp or IR laser. In this aspect, a UV exposure is followed by a second IR exposure, which generates localized heat needed for amplified photopolymer. The result is an intersection volume or exposed region between the first and second exposures by the first actinic radiation source 103a and the second actinic radiation source 103b, respectively, that will define the photo-defined polymer cross-section in 3D space.

In an aspect, the first actinic radiation source 103a may propagate a light along a first optical axis a₁ that is patterned by an associated first mask or reticle 104a, and the second actinic radiation source 103b may propagate a light along a second optical axis a₂ that is patterned by an associated second mask 104b.

In another aspect, as shown in FIG. 1, the first optical axis a₁ may have a first angle θ₁ with a central axis c, which is oriented orthogonally to the stage 106, and a second optical axis a₂ may have a second angle θ₂ with the central axis c. The first and second angles θ₁ and θ₂ may have a range of approximately 20 to 60 degrees, although there may be no physical limitations. In an aspect, the first and second angles θ₁ and θ₂ may be approximately 45° angles with respect to the central axis c. The control of the x-, y- and z- positions of the light propagated from the first actinic radiation source 103a and the second actinic radiation source 103b, respectively, may be a function of the first and second angles θ₁ and θ₂ and the first and second masks 104a and 104b.

In another aspect, the first and second masks 104a and 104b, respectively, may be positioned in mask mounts 105a and 105b. The first mask 104a may be one of a plurality of masks associated with the first actinic radiation source 103a to produce a desired first pattern and similarly, the second mask 104b may also be one of a plurality of masks associated with the second actinic radiation source 103b to produce a desired second pattern. In addition, the first mask 104a may be provided a first design for an angled exposure along the first optical axis a₁, and the second mask 104b provides a second design for an angled exposure along the second optical axis a₂.

In another aspect, the positioning of the mask mounts 105a and 105b may be adjustable, e.g. rotatable, to change the orientation of the masks relative to the respective optical axes, e.g., pre-selected angles. It should be understood that the positions of the first and second masks 104a and 104b and their respective mask mounts 105a and 105b, as shown in FIG. 1, are for illustrative purposes only and not intended to represent their actual positions in a lithographic patterning system, which may be directly above the photo-definable polymer layer 101.

In an aspect, the stage 106 provides a working surface for patterning the photo-definable polymer layer 101 and its position may be adjustable, e.g., tiltable. In an aspect, the movements of the masks and the stage may need to be synchronized to achieve the desired positions for shaping the photoresist material.

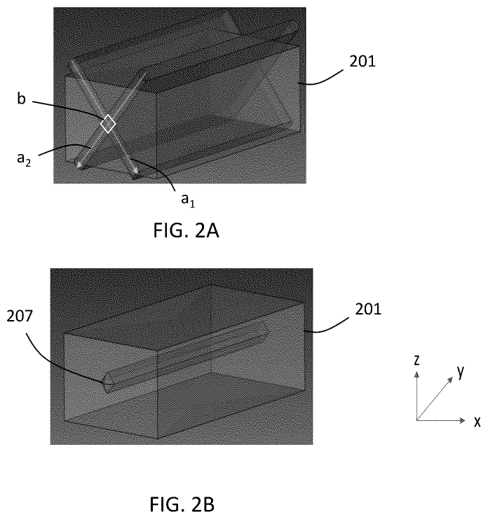

FIG. 2A shows an exemplary representation of two light paths a₁ and a₂ from two actinic radiation sources (not shown) and FIG. 2B shows a semiconductor component 207, i.e., a simple uniform and straight waveguide, formed at an intersection b of the two light paths a₁ and a₂ shown in FIG. 2A according to an aspect of the present disclosure. The semiconductor component 207 may be made from a photoresist material 201 that is shaped by a present lithographic patterning process. The process may be performed by a lithographic patterning system with first and second actinic radiation sources that direct, respectively, a first propagated light and a second propagated light to form an intersection within the photoresist material 201. The first propagated light initiates a partial formation of the semiconductor component 207 in the photoresist material 201 and the second propagated light completes the formation of the semiconductor component 207 in the photoresist material.

In another aspect, for a process using two UV exposures, the process may be performed by a lithographic patterning system having a single angle exposure that may generate a first propagated light and a second propagated light. The first propagate light may provide a first exposure to initiate a partial formation of a semiconductor component and the photoresist material may be rotated for the second propagated light to provide a second exposure to complete the formation of the semiconductor component. With proper mask design and alignment, this lithographic patterning system may provide the same effect as a system with two actinic radiation sources. In a further aspect, a lithographic patterning system with two angled propagate light projections may be achieved with a single actinic radiation source using two separate light bending apparatuses (not shown).

In an aspect, the actual size and shape of the intersection area may be modulated by the mask design of each angled exposure. For example, if the mean x- positions of the first and second actinic radiation sources along the y-axis are varied using an appropriate mask design, a waveguide may be made with bends in the x-y plane. In addition, if the distance between the two exposed intersections is varied at the same time, the waveguide may be moved in the z-direction as well.

In an aspect, the photoresist material 201 may be a standard negative photoresist based on epoxy-based polymer; for example, SU-8 brand photoresist, which is able to form a permanent resist pattern. Depending on the type of the photoresist polymer used, the subsequent step may be a development process to remove unexposed portions of the photoresist to form the actual optical element or other processes (e.g. baking) to enhance the refractive index contrast between the exposed and unexposed region.

In another aspect, the position control of the intersection area of the exposed region along the y-axis may be achieved by controlling the average position of the two exposures on the x-axis and their relative distance in the x-axis from a central axis, and the width of each individual exposure by controlling the corresponding locations on each of the masks used for the two exposures and the angle of the two exposure light sources. For example, assuming that the two angles of exposure are both at approximately 45 degrees with respect to the y,z plane at an arbitrary y0 position, if the mean position of the two angled exposure is x0 (measured at the surface of the photopolymer) and their distance is do at the surface of the photopolymer, then the center of the placement of the cross-section is (x0,y0, − sin(45)*d0). The actual size and shape of the cross-section area may be modulated by the mask design of each angled exposure.

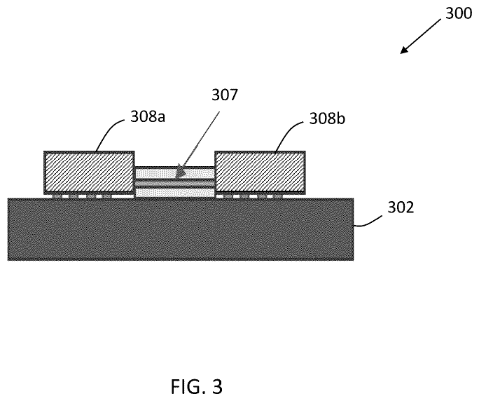

FIG. 3 shows an exemplary representation of a polymer waveguide 307 formed by a present lithographic patterning system in a silicon photonics package 300 according to an aspect of the present disclosure. The silicon photonics package 300 may include photonic integrated circuits 308a and 308b that are mounted on a substrate 302. In an aspect, the polymer waveguide 307 may be formed either pre- or post-mounting of the photonic integrated circuits 308a and 308b by using the measurements of the positions of the optical elements on the photonic integrated circuits 308a and 308b (e.g. the receive/transmit light interfaces). For example, the polymer waveguide 307 may be made using the present lithographic patterning system and method on the substrate 302 and the photonic integrated circuits 308a and 308b precisely aligned with the polymer waveguide 307. Alternatively, the photonic integrated circuits 308a and 308b may be mounted on the substrate 302 and the polymer waveguide 307 fabricated “insitu” by depositing a photoresist material and performing the present lithographic pattern method with alignments precisely based on the actual mounting positions of the two photonic integrated circuits 308a and 308b according to the present disclosure.

In an aspect, using the present method, there may be the capability to control the intersectional shape and the x,y, and z positions of the exposed area and make a range of different optical elements; for example, a diabatic taper may be made by gradually increase the x critical dimensions (the exposure beam size) along a y-axis of each angled exposures, while keeping their x position fixed. The resulting intersectional area along the y- direction may be slowly grown from small to large with the proper mask design.

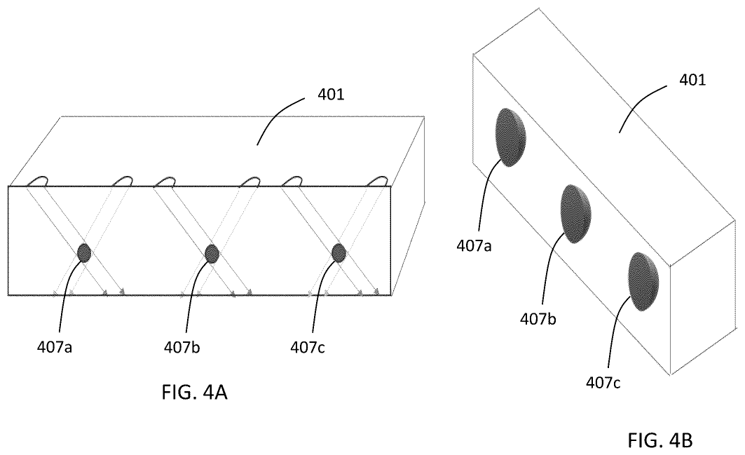

FIGS. 4A and 4B show an exemplary representation of multiple optic lenses 407a, 407b, and 407c, which may be formed by the present lithographic patterning system and method, according to an aspect of the present disclosure. In an aspect, the multiple optic lenses 407a, 407b, and 407c may be made in photoresist 401 using a single pass in the lithographic patterning system with very precise alignment. It is also possible to make multiple precisely aligned lenses with different shapes or a combination of waveguides and lenses in a single photoresist layer (not shown).

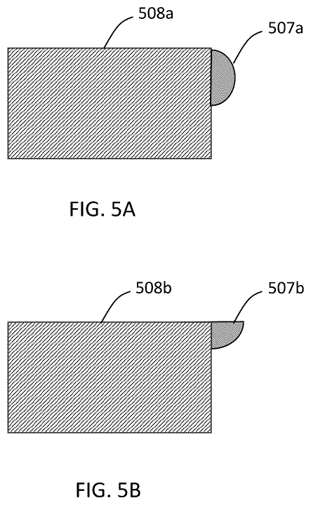

FIGS. 5A and 5B show exemplary representations of polymer optic lenses formed by a present lithographic patterning system attached to silicon photonics devices according to an aspect of the present disclosure. In FIG. 5A, a silicon photonic device 508a may include a polymer optic lens 507a, which is positioned at a side position. In FIG. 5B, a silicon photonic device 508b may include a half-sized polymer optic lens 507b, which is positioned at a side position. In an aspect, the polymer optic lenses 507a and 507b may be made using the present lithographic patterning system and method and attached, respectively, onto the silicon photonic devices 508a and 508b.

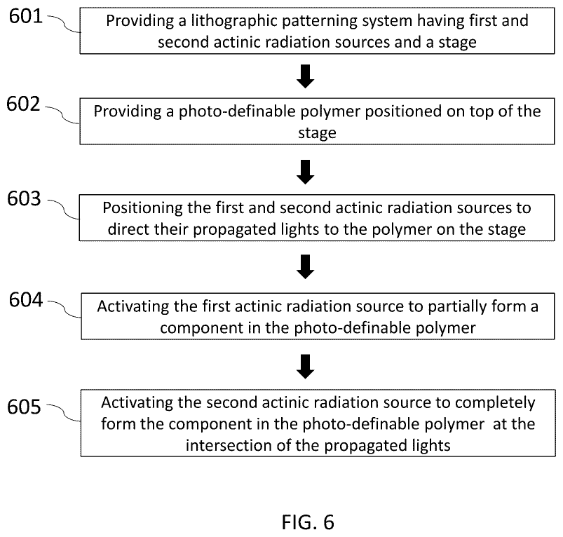

FIG. 6 shows a simplified flow diagram for another exemplary method according to an aspect of the present disclosure. In an aspect, the present method may be able to produce lithographically patterned components for high-volume manufacturing.

The operation 601 may be directed to providing a lithographic patterning system having first and second actinic radiation sources and a stage.

The operation 602 may be directed to providing a photo-definable polymer positioned on top of the stage.

The operation 603 may be directed to positioning the first and second actinic radiation sources to direct their propagated lights to the polymer on the stage.

The operation 604 may be directed to activating the first actinic radiation source to partially form a component in the photo-definable polymer.

The operation 605 may be directed to activating the second actinic radiation source to completely form the component in the photo-definable polymer at the intersection of the propagated lights.

It will be understood that any property described herein for a specific lithographic patterning system may also hold for any lithographic patterning system or tool described herein. It will also be understood that any property described herein for a specific method for patterning a photo-definable polymer may hold for any of the methods described herein. Furthermore, it will be understood that for any lithographic patterning system and the methods described herein, not necessarily all the components or operations described will be shown in the accompanying drawings or method, but only some (not all) components or operations may be disclosed.

To more readily understand and put into practical effect the present lithographic patterning system and patterning of a photo-definable polymer, they will now be described by way of examples. For the sake of brevity, duplicate descriptions of features and properties may be omitted.

### EXAMPLES

Example 1 provides a lithographic patterning system including a stage for supporting a substrate with a photo-definable polymer layer, for which the stage is orthogonal to a central axis, a first actinic radiation source, for which the first actinic radiation source is configured to propagate light along a first optical axis, a first mask for patterning the propagated light from the first actinic radiation source, a second actinic radiation source, for which the second actinic radiation source is configured to propagate light along a second optical axis, and a second mask for patterning the propagated light from the second actinic radiation source, for which the propagated light along the first optical axis from the first actinic radiation source forms an intersection in the photo-definable polymer layer with the propagated light along the second optical axis from the second actinic radiation source, and for which a patterned semiconductor component is formed at the intersection.

Example 2 may include the lithographic patterning system of example 1 and/or any other example disclosed herein, for which the first and second actinic radiation sources provide UV light.

Example 3 may include the lithographic patterning system of example 1 and/or any other example disclosed herein, for which the first actinic radiation source provides UV light and the second actinic radiation source provides IR light.

Example 4 may include the lithographic patterning system of example 2 and/or any other example disclosed herein, for which the first and second actinic radiation sources comprise UV lasers.

Example 5 may include the lithographic patterning system of example 1 and/or any other example disclosed herein, which further includes first and second mask mounts, for which the first and second mask mounts, respectively, are configurable to orient the surfaces of the first and second masks at pre-selected angles with respect to the first and second optical axes.

Example 6 may include the lithographic patterning system of example 1 and/or any other example disclosed herein, which further includes the first mask providing a first design for an angled exposure along the first optical axis.

Example 7 may include the lithographic patterning system of example 1 and/or any other example disclosed herein, which further includes the second mask providing a second design for an angled exposure along the second optical axis.

Example 8 may include the lithographic patterning system of example 1 and/or any other example disclosed herein, for which the first optical axis is at a first angle with respect to the central axis and the second optical axis is at a second angle with respect to the central axis.

Example 9 may include the lithographic patterning system of example 8 and/or any other example disclosed herein, for which the first angle and the second angle are at approximately 45° angles with respect to the central axis.

Example 10 provides a semiconductor component including a photoresist material shaped by a lithographic patterning process, the lithographic patterning process including providing a lithographic patterning system for generating a first propagated light and a second propagated light to form an intersection within the photoresist material, for which the first propagated light initiates a partial formation of the semiconductor component in the photoresist material and the second propagated light completes the formation of the semiconductor component in the photoresist material, and for which the semiconductor component is formed at the intersection within the photoresist material.

Example 11 may include the semiconductor component of example 10 and/or any other example disclosed herein, for which the shaped photoresist material is an optical waveguide for a silicon photonic package.

Example 12 may include the semiconductor component of example 10 and/or any other example disclosed herein, for which the shaped photoresist material is an optical lens or mirror for a silicon photonic package.

Example 13 provides a method providing a lithographic patterning system that delivers a first propagated light and a second propagated light including at least one actinic radiation source, a stage, and at least one mask for use with the actinic radiation source, generating and directing the first propagated light to the stage at a first angle relative to a central axis, for which the central axis is orthogonal to the stage, generating and directing the second propagated light to the stage at a second angle relative to the central axis, providing a photo-definable polymer positioned on top of the stage, activating the first actinic radiation source to partially form a semiconductor component in the photo-definable polymer, and activating the second actinic radiation source to completely form the component in the photo-definable polymer.

Example 14 may include the method of example 13 and/or any other example disclosed herein, which further includes the semiconductor component being formed at an intersection of the first and second propagated light from, respectively, the first and second actinic radiation sources.

Example 15 may include the method of example 14 and/or any other example disclosed herein, which further includes controlling an area of the intersection of the first and second actinic radiation sources by controlling the positioning of the first propagated light from the first actinic radiation source and distance along an x-axis from the central axis and by controlling the positioning of the second propagated light from second actinic radiation source and distance along the x-axis from the central axis.

Example 16 may include the method of example 15 and/or any other example disclosed herein, which further includes forming multiple semiconductor components using a single activation sequence of the first and second actinic radiation sources.

Example 17 may include the method of example 13 and/or any other example disclosed herein, which further includes consecutively activating the first actinic radiation source followed by activating the second actinic radiation source.

Example 18 may include the method of example 17 and/or any other example disclosed herein, for which the first actinic radiation source partially cures the photo-definable polymer and the second actinic radiation source completely cures the photo-definable polymer to form the component.

Example 19 may include the method of example 17 and/or any other example disclosed herein, for which the first and second actinic radiation sources provide UV light.

Example 20 may include the method of example 17 and/or any other example disclosed herein, for which the first actinic radiation source provides UV light and the second actinic radiation source provides IR light.

The term “comprising” shall be understood to have a broad meaning similar to the term “including” and will be understood to imply the inclusion of a stated integer or operation or group of integers or operations but not the exclusion of any other integer or operation or group of integers or operations. This definition also applies to variations on the term “comprising” such as “comprise” and “comprises”.

The term “coupled” (or “connected”) herein may be understood as electrically coupled or as mechanically coupled, e.g., attached or fixed or attached, or just in contact without any fixation, and it will be understood that both direct coupling or indirect coupling (in other words: coupling without direct contact) may be provided.

The terms “and” and “or” herein may be understood to mean “and/or” as including either or both of two stated possibilities.

While the present disclosure has been particularly shown and described with reference to specific aspects, it should be understood by those skilled in the art that various changes in form and detail may be made therein without departing from the spirit and scope of the present disclosure as defined by the appended claims. The scope of the present disclosure is thus indicated by the appended claims and all changes which come within the meaning and range of equivalency of the claims are therefore intended to be embraced.

What is claimed is:

1. A lithographic patterning system comprising:
a stage for supporting a substrate with a photo-definable polymer layer, wherein the stage is orthogonal to a central axis;
a first actinic radiation source, wherein the first actinic radiation source is configured to propagate light along a first optical axis;
a first mask for patterning the propagated light from the first actinic radiation source;
a second actinic radiation source, wherein the second actinic radiation source is configured to propagate light along a second optical axis; and
a second mask for patterning the propagated light from the second actinic radiation source;
wherein the propagated light along the first optical axis from the first actinic radiation source forms an intersection in the photo-definable polymer layer with the propagated light along the second optical axis from the second actinic radiation source, and
wherein a patterned semiconductor component is formed at the intersection.

2. The lithographic patterning system of claim 1, wherein the first and second actinic radiation sources provide UV light.

3. The lithographic patterning system of claim 1, wherein the first actinic radiation source provides UV light and the second actinic radiation source provides IR light.

4. The lithographic patterning system of claim 2, wherein the first and second actinic radiation sources comprise UV lasers.

5. The lithographic patterning system of claim 1, further comprises first and second mask mounts, wherein the first and second mask mounts, respectively, are configurable to orient the surfaces of the first and second masks at pre-selected angles with respect to the first and second optical axes.

6. The lithographic patterning system of claim 1, further comprises the first mask providing a first design for an angled exposure along the first optical axis.

7. The lithographic patterning system of claim 1, further comprises the second mask providing a second design for an angled exposure along the second optical axis.

8. The lithographic patterning system of claim 1, wherein the first optical axis is at a first angle with respect to the central axis and the second optical axis is at a second angle with respect to the central axis.

9. The lithographic patterning system of claim 8, wherein the first angle and the second angle are at approximately 45° angles with respect to the central axis.

10. A semiconductor component comprising:
a photoresist material shaped by a lithographic patterning process, the lithographic patterning process comprising:
providing a lithographic patterning system for generating a first propagated light and a second propagated light to form an intersection within the photoresist material,
wherein the first propagated light initiates a partial formation of the semiconductor component in the photoresist material and the second propagated light completes the formation of the semiconductor component in the photoresist material, and
wherein the semiconductor component is formed at the intersection within the photoresist material.

11. The semiconductor component of claim 10, wherein the shaped photoresist material is an optical waveguide for a silicon photonic package.

12. The semiconductor component of claim 10, wherein the shaped photoresist material is an optical lens or mirror for a silicon photonic package.

13. A method comprising:
providing a lithographic patterning system that delivers a first propagated light and a second propagated light comprising at least one actinic radiation source, a stage, at least one mask for use with the actinic radiation source;
generating and directing the first propagated light to the stage at a first angle relative to a central axis, wherein the central axis is orthogonal to the stage;
generating and directing the second propagated light to the stage at a second angle relative to the central axis;
providing a photo-definable polymer positioned on top of the stage;
activating the actinic radiation source to partially form a semiconductor component in the photo-definable polymer; and
activating the actinic radiation source for a second time or providing and activating a second actinic radiation source to generate the second propagated light to completely form the semiconductor component in the photo-definable polymer.

14. The method of claim 13, further comprises the semiconductor component being formed at an intersection of the first and second propagated lights from, respectively, the first and second actinic radiation sources.

15. The method of claim 14, further comprises controlling an area of the intersection of the first and second actinic radiation sources by controlling the positioning of the first propagated light from the first actinic radiation source and distance along an x-axis from the central axis and by controlling the positioning of the second propagated light from second actinic radiation source and distance along the x-axis from the central axis.

16. The method of claim 15, further comprises forming multiple semiconductor components using a single activation sequence of the first and second actinic radiation sources.

17. The method of claim 13, further comprises consecutively activating the first actinic radiation source followed by activating the second actinic radiation source.

18. The method of claim 17, wherein the first actinic radiation source partially cures the photo-definable polymer and the second actinic radiation source completely cures the photo-definable polymer to form the component.

19. The method of claim 17, wherein the first and second actinic radiation sources provide UV light.

20. The method of claim 17, wherein the first actinic radiation source provides UV light and the second actinic radiation source provides IR light.
